(19) United States
(12) Patent Application Publication
(10) Pub. No.: US 2011/0011455 A1
(43) Pub. Date: Jan. 20, 2011

(54) INTEGRATED SOLAR CELL WITH WAVELENGTH CONVERSION LAYERS AND LIGHT GUIDING AND CONCENTRATING LAYERS

(75) Inventors: Jin Ji, Boston, MA (US); Lawrence A. Kaufman, Waltham, MA (US); W. Dennis Slafer, Arlington, MA (US)

Correspondence Address: Milstein Zhang & Wu LLC, 49 Lexington Street, Suite 6, Newton, MA, 02465-1062, US

(73) Assignee: LIGHTWAVE POWER, INC., CAMBRIDGE, MA (US)

(21) Appl. No.: 12/921,388

(22) PCT Filed: Mar. 11, 2009
(86) PCT No.: PCT/US09/36815

§ 371 Date: Sep. 7, 2010

Related U.S. Application Data
(60) Provisional application No. 61/035,510, filed on Mar. 11, 2008.
(60) Provisional application No. 61/116,755, filed on Nov. 21, 2008.
(60) Provisional application No. 61/116,743, filed on Nov. 21, 2008.
(60) Provisional application No. 61/147,937, filed on Jan. 28, 2009.

(51) Int. Cl. H01L 31/0216; H01L 31/055

(52) U.S. Cl. 136/257

(57) ABSTRACT

The invention relates to an integrated solar cell which includes a plasmonic layer which includes a pattern configured to support plasmon waves, The plasmonic layer is configured to receive as input light energy of an incident light and at least one photon of light received from one or more layers in optical communication with the plasmonic layer and to re-emit as output a guided light to the one or more layers in optical communication with the plasmonic layer. A wavelength conversion layer is configured to receive as input at least one photon having a first wavelength and to provide as output at least one photon having a second wavelength different than the first wavelength. A photovoltaic layer is optically coupled to both the wavelength conversion layer and the plasmonic layer, the photovoltaic layer configured to convert at least one photon having the second wavelength to electrical energy.

### CROSS-REFERENCE TO RELATED APPLICATIONS

This application claims priority to and the benefit of co-pending U.S. provisional patent application Ser. No, 61/035,510, entitled THIN FILM ELEMENT FOR ABSORBING, SHIFTING AND REEMITTING ELECTROMAGNETIC WAVES, filed Mar. 11, 2008, co-pending U.S. provisional patent application Serial No. 61/116,743, entitled TWO-DIMENSIONAL PHOTONIC CRYSTAL STRUCTURES, filed Nov. 21, 2008, co-pending U.S. provisional patent application Ser. No. 61/116,755, entitled PERIODIC OR NON-PERIODIC NANOSTRUCTURES TO CONTROL EMISSION ENVIRONMENT FOR ENHANCED WAVELENGTH SHIFTING EFFICIENCY filed Nov. 21, 2008, co-pending U.S. provisional patent application Ser. No. 61/147,937, filed Jan. 28, 2009, entitled IMPROVING EFFICIENCIES OF PV CELLS USING PLASMONIC AND PHOTOVOLTAIC NANOARRAYS, which applications are incorporated herein by reference in their entirety. This application is also related to co-pending PCT Application No. , entitled INTEGRATED PLANAR DEVICE FOR LIGHT GUIDING, CONCENTRATING, AND WAVELENGTH SHIFTING, filed Mar. 11, 2009, which is incorporated by reference in its entirety.

### FIELD OF THE INVENTION

The invention relates in general to an integrated solar cell, and more particularly to an integrated solar cell including wavelength shifting.

### BACKGROUND OF THE INVENTION

Solar cells that convert an incident light to electricity are becoming increasingly important in a variety of applications. Such applications range from powering small devices to powering our national power grid. Solar cell light to electricity conversion efficiency is important both to maximize the electrical output for a given solar cell area, as well as to provide more cost effective solar cells. A limiting factor for solar cell light to electricity conversion efficiency is that most solar cells can only convert light within a certain bandwidth to electricity. Light energy light having a wavelength outside of that bandwidth is wasted.

One way to make more efficient solar cells is to create a more efficient photovoltaic layer. Material and manufacturing advances have improved the efficiency of single photovoltaic layers, particularly in recent years. Unfortunately, theoretical efficiency limits for single layer solar cells ultimately limits single layer solar cell to performance levels below the desired conversion efficiencies.

Another approach to improved solar cell efficiency uses multiple photovoltaic layers. Some success has been achieved, for example, by stacking multiple photovoltaic layers having different bandwidths of wavelength sensitivity. Using such a stacking approach provides a somewhat broader bandwidth sensitivity that results in some gain in conversion efficiency.

More recently, solar cells having plasmonic layers have been proposed. Plasmonic layers can direct light in ways that can lead to a more efficient conversion of incident light to electricity. For example, Atwater described a plasmonic photovoltaic device in U.S. Published Patent Application No. U.S. 2007/0289623 A1, Plasmonic Photovoltaics, published Dec. 20, 2007. Yet, even with the addition of plasmonic layers, it would be desirable to find new structures that can still further improve the efficiency of integrated solar cells,

Therefore, what is needed is a new integrated solar cell structure having still higher efficiencies than can be achieved by use of conventional plasmonic photovoltaics alone.

### SUMMARY OF THE INVENTION

In one aspect, the invention relates to an integrated solar cell which includes a plasmonic layer which includes a pattern configured to support plasmon waves. The plasmonic layer is configured to receive as input light energy of an incident light and at least one photon of light received from one or more layers in optical communication with the plasmonic layer and to re-emit as output a guided light to the one or more layers in optical communication with the plasmonic layer. The integrated solar cell also includes a wavelength conversion layer optically coupled to the plasmonic layer. The wavelength conversion layer is configured to receive as input at least one photon having a first wavelength and to provide as output at least one photon having a second wavelength different than the first wavelength. The integrated solar cell also includes a photovoltaic layer optically coupled to both the wavelength conversion layer and the plasmonic layer, the photovoltaic layer configured to convert at least one photon having the second wavelength to electrical energy.

In one embodiment, the guided light includes a concentrated light.

In another embodiment, the incident light includes light falling within a terrestrial solar spectrum.

In yet another embodiment, the plasmonic layer includes a film having a thickness of comparable dimension to a skin depth of a photon of the incident light.

In yet another embodiment, the pattern includes a plurality of shapes selected from the group consisting of rods, rectangles, triangles, linear ridges, circular ridges, spiral ridges, and stars.

In yet another embodiment, the shapes has a physical dimension of about a wavelength of the incident light.

In yet another embodiment, the pattern has a pattern distribution selected from the group consisting of a periodic pattern distribution, a non-periodic pattern distribution, and a random pattern distribution.

In yet another embodiment, one or more of the shapes include a protrusion extending outward from a surface of the film.

In yet another embodiment, one or more of the shapes include a depression extending into a surface of the film.

In yet another embodiment, one or more of the shapes includes a void extending trough both a first surface and a second surface of the film.

In yet another embodiment, one or more of the shapes includes a void surrounded by a plurality of protrusions.

In yet another embodiment, one or more of the shapes includes a void surrounded by a plurality of depressions.

In yet another embodiment, the film includes an electrically conductive film.

In yet another embodiment, the electrically conductive film includes a selected one of a metal and an alloy made from metals selected from the group consisting of gold, silver, chromium, titanium, copper, and aluminum.

In yet another embodiment, the electrically conductive film includes a transparent conductive oxide layer,

In yet another embodiment, the transparent conductive oxide includes a selected one of an indium-tin-oxide (ITO) and a zinc oxide (ZnO),

In yet another embodiment, the plasmonic layer includes a plurality of patches disposed on a surface, each one of the patches having a thickness of comparable dimension to a skin depth of a photon of the incident light.

In yet another embodiment, each one of the patches has a shape selected from the group consisting of rods, tubes, rectangles, triangles, linear ridges, circular ridges, spirals, spiral ridges, and stars.

In yet another embodiment, each of the shapes has a physical dimension of about a wavelength of the incident light.

In yet another embodiment, the pattern has a pattern distribution selected from the group consisting of a periodic pattern distribution, a non-periodic pattern distribution, and a random pattern distribution.

In yet another embodiment, the surface includes an optically conductive substrate.

In yet another embodiment, the surface includes a surface of a selected one of the wavelength conversion layer and the photovoltaic layer.

In yet another embodiment, each one of the patches includes an electrically conductive material.

In yet another embodiment, the electrically conductive material includes a metal selected from the group consisting of gold, silver, chromium, titanium, copper, and aluminum.

In yet another embodiment, the electrically conductive material includes a transparent conductive oxide layer.

In yet another embodiment, the transparent conductive oxide includes a selected one of an indium-tin-oxide (ITO) and a zinc oxide (ZnO).

In yet another embodiment, the plasmonic layer is configured such that a received photon causes a selected one of an electric field and a magnetic field to have a higher field strength near each of the patches as compared to a field strength in a void between the patches.

In yet another embodiment, the photovoltaic layer includes a photovoltaic material selected from the group consisting of an amorphous silicon photovoltaic material, a micro-crystalline silicon photovoltaic material, a nano-crystalline silicon photovoltaic material, a crystalline silicon photovoltaic material, a cadmium telluride (CdTe) photovoltaic material, a copper indium germanium selenium (CIGS), and an organic photovoltaic material.

In yet another embodiment, the integrated solar cell further includes a substantially optically transparent electrically conductive layer disposed between the plasmonic layer and the wavelength conversion layer, the substantially optically transparent electrically conductive layer configured to improve an electrical contact between the plasmonic layer and the wavelength conversion layer.

In yet another embodiment, the integrated solar cell further includes a substantially optically transparent electrically conductive layer disposed between the wavelength conversion layer and the photovoltaic layer, the substantially optically transparent electrically conductive layer configured to improve an electrical contact between the wavelength conversion layer and the photovoltaic layer.

In yet another embodiment, a first plasmonic layer is disposed adjacent to a first surface of the wavelength conversion layer and a second plasmonic layer disposed between a second surface of the wavelength conversion layer and the photovoltaic layer.

In yet another embodiment, the integrated solar cell further includes a substantially optically transparent electrically conductive layer disposed between any two layers of the integrated solar cell, the substantially optically transparent electrically conductive layer configured to improve an electrical contact between the any two layers of the integrated solar cell.

In yet another embodiment, the integrated solar cell further includes a plurality of photovoltaic layers.

In yet another embodiment, the wavelength conversion layer is configured to receive as input at least one photon having a first wavelength and to provide as output at least one photon having a second wavelength longer than the first wavelength.

In yet another embodiment, the wavelength conversion layer includes a selected one of a phosphor and a fluorophore.

In yet another embodiment, the wavelength conversion layer includes a material doped with one or more rare earth ions.

In yet another embodiment, the wavelength conversion layer includes a material doped with a first rare-earth ion and a second rare earth ion, wherein the first rare-earth ion is configured to absorb at least one photon having the first wavelength and the second rare earth ion is configured to emit at least one photon having the second wavelength longer than the first wavelength.

In yet another embodiment, the wavelength conversion layer includes at least one rare earth ion selected from the group consisting of Pr3+, Eu3+, Ce3+, Tm3+, and Yb3+.

In yet another embodiment, the wavelength conversion layer includes a substantially optically transparent matrix.

In yet another embodiment, the substantially optically transparent matrix includes a material selected from the group consisting of glass, ceramic, and polymer.

In yet another embodiment, the substantially optically transparent matrix includes a substantially transparent adhesive,

In yet another embodiment, the wavelength conversion layer includes a plurality of quantum dots.

In yet another embodiment, the wavelength conversion layer is doped with a conductive element and the wavelength conversion layer is electrically coupled to at least one adjacent layer.

In yet another embodiment, the wavelength conversion layer is configured to receive as input at least one photon having a first wavelength and to provide as output at least one photon having a second wavelength shorter than the first wavelength.

In yet another embodiment, the wavelength conversion layer includes a phosphor.

In yet another embodiment, the wavelength conversion layer includes a material doped with one or more rare earth ions.

In yet another embodiment, the wavelength conversion layer includes a material doped with a first rare-earth ion and a second rare earth ion, wherein the first rare-earth ion is configured to absorb at least one photon having the first wavelength and the second rare earth ion is configured to emit at least one photon having the second wavelength shorter than the first wavelength.

In yet another embodiment, the wavelength conversion layer includes at least one rare earth ion selected from the group consisting of Er3+, Yb3+, and Nd3+.

In yet another embodiment, the wavelength conversion layer includes a substantially optically transparent matrix.

In yet another embodiment, the substantially optically transparent matrix includes a material selected from the group consisting of glass, ceramic, and polymer.

In yet another embodiment, the substantially optically transparent matrix includes a substantially transparent adhesive.

In yet another embodiment, the wavelength conversion layer includes a nonlinear material configured to absorb two photons having a first wavelength and to provide as output at least one photon having a second wavelength that is substantially one half of the first wavelength.

In yet another embodiment, the wavelength conversion layer includes a nonlinear material configured to absorb three photons having a first wavelength and to provide as output at least one photon having a second wavelength that is substantially one third of the first wavelength.

In yet another embodiment, the wavelength conversion layer includes at least one material selected from the group of materials consisting of organic material, inorganic material, optical material, and crystal material.

In yet another embodiment, the wavelength conversion layer includes at least one material selected from the group of materials consisting of β-Barium Borate (BBO), potassium dihydrogen phosphate (KDP), potassium titanyl phosphate (KTP), Lithium Niobate (LiNbO3), polydiacetylenes, poly-3-butoxy-carbonyl-methyl-urethane (poly(3BCMU)), poly-3-butoxy-carbonyl-methyl-urethane (poly(4-BCMU))), and dendritic nonlinear organic glass.

In yet another embodiment, the wavelength conversion layer is doped with a conductive element and the wavelength conversion layer is electrically coupled to at least one adjacent layer.

In yet another embodiment, the wavelength conversion layer further includes one or more semiconducting materials and the wavelength conversion layer is configured to broaden a bandwidth of absorption wavelength.

In yet another embodiment, the integrated solar cell includes at least one additional wavelength conversion layer and at least one wavelength conversion layer configured to receive as input at least one photon having a first wavelength and to provide as output at least one photon having a second wavelength longer than the first wavelength and at least one wavelength conversion layer configured to receive as input at least one photon having a first wavelength and to provide as output at least one photon having a second wavelength shorter than the first wavelength.

In another aspect, according to the invention, an integrated solar cell includes a photovoltaic layer configured to receive as input light energy of an incident light and to convert at least one photon having a second wavelength to electrical energy and to re-emit as output an emitted light to one or more layers in optical communication with the photovoltaic layer. The integrated solar cell also includes a wavelength conversion layer optically coupled to the photovoltaic layer, the wavelength conversion layer configured to receive as input at least one photon having a first wavelength and to provide as output at least one photon having the second wavelength different than the first wavelength. The integrated solar cell also includes a plasmonic layer including a pattern configured to support plasmon waves. The plasmonic layer is configured to receive as input a light energy of the emitted light and to re-emit as output a guided light to one or more layers in optical communication with the plasmonic layer. The integrated solar cell also includes a reflector mirror layer in optical communication with the plasmonic layer and configured to reflect at least one photon of the incident light and at least one photon having the second wavelength towards the plasmonic layer.

In one embodiment, the guided light includes a concentrated light.

In another embodiment, the integrated solar cell further includes a substantially optically transparent electrically conductive layer disposed between any two layers of the integrated solar cell, the substantially optically transparent electrically conductive layer configured to improve an electrical contact between the any two layers of the integrated solar cell.

In yet another embodiment, the integrated solar cell further includes at least one additional photovoltaic layer disposed between the photovoltaic layer and the reflector mirror.

In yet another embodiment, the integrated solar cell further includes at least one additional plasmonic layer disposed between any two layers of the integrated solar cell.

In yet another embodiment, the integrated solar cell further includes at least one additional wavelength conversion layer disposed between the photovoltaic layer and the reflector mirror.

In yet another embodiment, the integrated solar cell includes at least one wavelength conversion layer configured to receive as input at least one photon having a first wavelength and to provide as output at least one photon having a second wavelength longer than the first wavelength and at least one wavelength conversion layer configured to receive as input at least one photon having a first wavelength and to provide as output at least one photon having a second wavelength shorted than the first wavelength.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 shows a block diagram of one exemplary embodiment of an integrated solar cell with wavelength down shifting.

FIG. 2 shows a block diagram of an exemplary embodiment of an integrated solar cell with wavelength up shifting.

FIG. 3 shows a cross section drawing of an exemplary light absorbing and concentrating structure having a combination of holes and surrounding ridges.

FIG. 4 shows a cross section drawing of an exemplary light absorbing and concentrating structures having periodic holes.

FIG. 5 shows a cross section drawing of an exemplary light absorbing and concentrating structures having a periodic array of rods.

FIG. 6 shows a cross section drawing of an exemplary light absorbing and concentrating structures having a random array of rods.

FIG. 7 shows a cross section drawing of an exemplary light absorbing and concentrating structures having a periodic array of tubes.

FIG. 8 shows a cross section drawing of an exemplary light absorbing and concentrating structures having a random array of tubes.

FIG. 9 shows a cross section drawing of an exemplary light absorbing and concentrating structures having a combination of tubes and depressions.

FIG. 10 shows a cross section drawing of an exemplary light absorbing and concentrating structures shown as combination of rods and depressions.

FIG. 11 shows a cross section drawing of an exemplary light absorbing and concentrating structures having a combination of rods and ridges.

FIG. 12 shows a cross section drawing of an exemplary light absorbing and concentrating structures having a combination of tubes and ridges.

FIG. 13 shows a cross section drawing of an exemplary light absorbing and concentrating structures having a combination of hole, tube and rod.

FIG. 14 shows a top view drawing of an exemplary absorbing and concentrating structures having interpenetrating spiral grooves with a nanohole substantially at the center.

FIG. 15 shows one embodiment of an exemplary light absorbing, concentrating, shifting and reemiting structure.

FIG. 16 shows a block diagram of one embodiment of an integrated solar cell with down shifting having a plurality of photovoltaic layers.

FIG. 17 shows a block diagram of one embodiment of an integrated solar cell with up shifting having a plurality of photovoltaic layers.

FIG. 18 shows a block diagram of one embodiment of an integrated solar cell with a down shifting wavelength conversion layer and two plasmonic layers.

FIG. 19 shows a block diagram of one embodiment of an integrated solar cell with an up shifting wavelength conversion layer and two plasmonic layers.

FIG. 20 shows a block diagram of one exemplary embodiment of an integrated solar cell with wavelength conversion having a reflector layer.

FIG. 21 shows another exemplary embodiment of an integrated solar cell with wavelength conversion and a reflector layer.

FIG. 22 shows one exemplary embodiment of an integrated film with a wavelength shifting layer.

FIG. 23 shows one exemplary embodiment of an integrated film suitable for use in an article of clothing to keep a person warm.

FIG. 24 shows one exemplary embodiment of an integrated film suitable for use in an article of clothing to keep a person cool.

FIG. 25 shows a block diagram of a mechanically moveable or retractable plasmonic layer.

FIG. 26 shows an embodiment of a temperature regulating integrated film having shapes on a movable substrate.

### DETAILED DESCRIPTION OF THE INVENTION

The detailed description is divided into three parts. In Part I some relevant terms and phrases are defined. In Part II, various embodiments of an integrated solar cell with wavelength shifting are described. Part III describes integrated films with wavelength shifting, such as those useful in camouflage applications.

### Part I, Definitions:

Wavelength shifting materials

Wavelength shifting materials, also called wavelength conversion materials (materials of wavelength conversion layers) include materials that can absorb in one wavelength and emit in another wavelength. Wavelength shifting materials can be up-converting in wavelength (upconversion, up shifting) or down-converting in wavelength (downconversion, down shifting) materials. Such materials can include linear and nonlinear materials. A downconversion material absorbs at least one photon and emits one or more photons having wavelength longer than the absorbed photon. Examples of downconversion materials include, but are not limited to, phosphors, fluorophors, and semi-conducting materials such as quantum dots. Other examples of downconversion materials include materials doped with one type of rare earth ions. Another example of a downconversion material is a material that is doped with at least two different types of rare earth ions, where at least one ion from a first type of rare earth ion absorbs an incident photon, and transfers the energy to two or more rare earth ions from a second type to emit two or more photon of longer wavelength. Examples of the rare earth ions are, but are not limited to, Pr³⁺, Eu³⁺, Ce^{3+, Tm}³⁺, or Yb³⁺. An upconversion material absorbs at least one photon and emits at least one photon having wavelength shorter than the absorbed photon. Upconversion materials include, but are not limited to, phosphors. Other examples of upconversion materials include materials doped with one or more types of rare earth ions such as Er³⁺,Yb³⁺ or Nd³⁺. Both up and down conversion materials can also be directly deposited on the surface of an adjacent layer, or be physically dispersed in a transparent matrix such as an adhesive and attached to an adjacent layer. Some wavelength conversion materials are of crystal form and can be formed in a transparent matrix such as glass, ceramic or polymer.

### Plasmonic Structures

Plasmonic structures are structures that can support propagating or standing collective electron oscillation, also called plasmon waves. Materials for such structures include, but are not limited to, metallic or conductive materials. Examples of suitable materials include, but are not limited to, gold (Au), silver (Ag), copper (Cu), aluminum (Al), indium tin oxide (ITO), zinc oxide (ZnO), silicon or chromium (Cr). Plasmonic structures can also exhibit some properties of a photonic structure such as band gap and light guiding.

### Plasmons

Plasmons are collective oscillations of the free electrons in a metal or conductive material. Plasmonic structures can be used to generate an enhanced electric field and/or magnetic field by generating resonance between an incident electromagnetic wave and plasmon waves in the structure. In some embodiments, when coupling wavelength shifting materials, such as nonlinear wavelength shifting materials with such structures, wavelength-shifting efficiency can be improved due to enhanced electric or magnetic field. As is well known, an electric field and a magnetic field are two components of an electromagnetic field. Plasmonic structures can also be used to enhance an electric field, a magnetic field or both an electric field and a magnetic field. Plasmonic structures can also be used to absorb certain range of wavelengths efficiently and redirect the light to an adjacent layer.

### Geometry of Patterns (Including Distributions of Shapes):

Geometry of Patterns and distributions of shapes refer to the geometry of a periodic or non-periodic pattern of a plasmonic structure, also called a plasmonic layer. The geometry of the pattern can be symmetric which can minimize various effects induced by various degrees of polarization, coherency and angle of incident sunlight. Examples of such symmetry include, but are not limited to, spherical, hexagonal, square, triangular, etc. Such structures can also be made non-symmetric to achieve an enhanced electric and/or magnetic field. The geometry of arrays can also determine an optimum range of wavelengths of incident light that can be resonant with the plasmon waves in a plasmonic structure and induce enhanced electric and/or magnetic fields, or the efficiency of absorption and redirection of an incident light.

### Quantum Dots

Quantum dots can include a variety of geometries including, for example, quantum dots which are spherical in shape, quantum spikes, quantum stars, etc. Quantum dots are nanocrystals or microcrystals that contain a droplet of electrons (due to the confined size of the quantum particle). The nanocrystals or microcrystals are typically semiconductor nanocrystals or microcrystals. Made of semiconducting materials, quantum dots can absorb a wide range of wavelengths of light and re-emit the light in a narrow range of wavelength of light. As described in more detail below, quantum dots can be used in solar applications, such as solar cell applications, including wavelength conversion. In some embodiments, quantum dots can be used to broaden the absorption bandwidths of some wavelength shifting materials such as, for example, rare earth ion doped materials. Quantum dots can either replace the absorbing element of a wavelength conversion material to absorb a wide range of light and transfer the energy to the emitting element of a wavelength conversion material, or can be added into a wavelength conversion material to absorb a wide range of light and transfer the energy to the absorbing element of a wavelength conversion material.

Part II, Integrated Solar Cells with Wavelength Shifting:

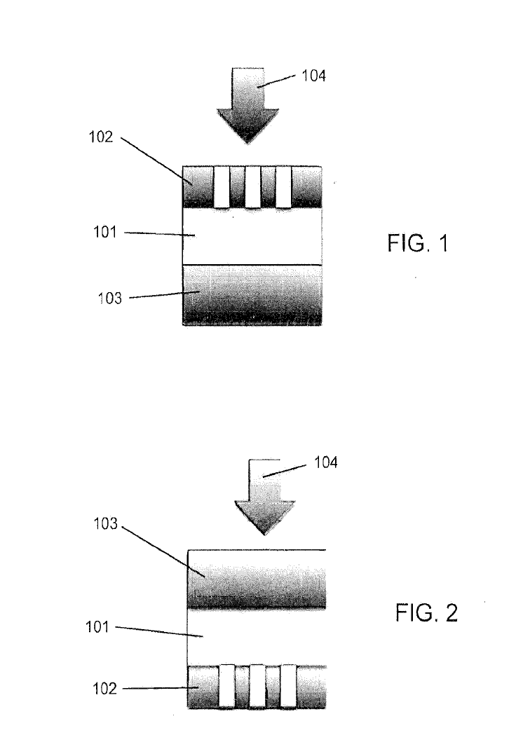

FIG. 1 shows a block diagram of one exemplary embodiment of an integrated solar cell with wavelength shifting. A plasmonic layer 102 includes a pattern configured to support plasmon waves. Plasmonic layer 102 can receive as input light energy of an incident light 104 and at least one photon of light received from one or more other layers in optical communication with it. Plasmonic layer 102 can also re-emit as output a guided light to any of the other layers. Typically, a light output from a plasmonic layer 102 is a more concentrated light (higher intensity) as compared with an incident light 104. A wavelength conversion layer (wavelength shifting) 101 is optically coupled to plasmonic layer 102. Wavelength conversion layer 101 receives as input at least one photon having a first wavelength and provides as output at least one photon having a second wavelength different than the first wavelength. In the exemplary embodiment shown in FIG. 1 wavelength conversion layer 101 is typically a down shifting (downconversion) wavelength conversion layer. A down shifting wavelength conversion layer converts at least one photon having a first wavelength to at least one photon having a second wavelength longer than the first wavelength. A photovoltaic layer 103 is optically coupled to other layers of the integrated solar cell structure, such as the wavelength conversion layer 101 and the plasmonic layer 102. In some cases, one or more photons of the incident light can also be directly converted by photovoltaic layer 103 to electrical energy. In other cases, e.g. where most or all of the energy of the incident light 104 is not within a bandwidth suitable for direct conversion by photovoltaic layer 103, photovoltaic layer 103 converts photons of the second wavelength to electricity. Plasmonic layer 102 can selectively guide a portion of the incident light 104 that is within a bandwidth suitable for direct conversion by photovoltaic layer 103 to photovoltaic layer 103 directly, as well as guide the portion of the incident light 104 that is not within a bandwidth suitable for direct conversion by photovoltaic layer 103 to wavelength conversion layer 101. Wavelength conversion layer 101 typically emits photons of the second wavelength in an isotropic radiation pattern. Plasmonic layer 102 can also be designed to guide the second wavelength emitted from wavelength conversion layer 101 to photovoltaic layer 103. Therefore, photovoltaic layer 103 can receive photons of the second wavelength either directly from the wavelength conversion layer 101 or indirectly from the wavelength conversion layer 101 via a plasmonic layer 102. A plurality of patterns can be disposed on or in a single plasmonic layer 102 or there can be a plurality of plasmonic layers 102.

FIG. 2 shows another exemplary embodiment of an integrated solar cell with wavelength shifting. In the exemplary embodiment shown in FIG. 2, wavelength conversion layer 101 is typically an up shifting (upconversion) wavelength conversion layer. An up shifting wavelength conversion layer converts at least one photon having a first wavelength to at least one photon having a second wavelength shorter than the first wavelength. As can be seen by the embodiment of FIG. 2, while layers of an integrated solar cell with wavelength shifting are typically in optical communication with each other, the order of the layers can be varied for a given application. Also, as is described below in more detail, integrated solar cell can have multiple plasmonic layers 102, wavelength conversion layers 101, and photovoltaic layers 103.

Integrated solar cells can be used to convert an incident light falling within a terrestrial solar spectrum. Such applications typically include green power solar generation applications. Integrated solar cells can also be particularly useful in other applications, for example in applications where the incident light has little energy that can be directly converted by one or more photovoltaic layers. In such applications, most of the photons which are converted to electricity are those which are wavelength shifted by a wavelength conversion layer 101. Also, as described above, since wavelength conversion layers 101 typically emit wavelength converted light in an isotropic radiation pattern, one or more plasmonic layers 102 can redirect wavelength converted light that would not otherwise reach one or more photovoltaic layers 103, thus enhancing the efficiency of the integrated solar cell.

### Plasmonic Layer

As described above, a plasmonic layer includes a pattern designed to support plasmon waves. The plasmonic layer can be fabricated either as a film with physical features or as a collection of patches or “islands” formed on a surface. In general, a plasmonic layer accepts light as input and there can be a resonance between the input light and plasmon waves caused by the pattern of the plasmonic layer. The plasmonic layer can then output a directed or concentrated light.

Embodiments of integrated solar cells having a plasmonic layer fabricated as a film having physical features are now described in more detail. A film with physical features has a thickness of comparable dimension to a skin depth of a photon of light (e.g. a wavelength range of the terrestrial solar spectrum). The pattern of the plasmonic layer can include a plurality of shapes such as, rods, rectangles, triangles, linear ridges, circular ridges, spiral ridges, and stars. Each one of the shapes can also have a physical dimension of about a wavelength of light, such as in a wavelength range of the terrestrial solar spectrum. The pattern of a plasmonic layer can have a variety of pattern distributions. For example, the pattern distribution can be a periodic pattern distribution, a non-periodic pattern distribution, and a random pattern distribution. The physical features in a plasmonic film structure can be protrusions extending outward from a surface of the film, depressions extending into a surface of the film, or voids extending through both surfaces of the film. The physical features can also include any combination of two or more types of protrusions, depressions, or voids. For example, a pattern can be formed from a shape having a void surrounded by one or more protrusions. Or, a pattern can be formed from a shape having a void surrounded by a plurality of depressions. On receiving a photon, a plasmonic layer formed from a distribution of voids, protrusions and/or depressions can cause there to be a higher electric and/or magnetic field strength near some voids (spaces), protrusions or depressions as compared to the field strength in film areas between the voids, protrusions or depressions.

In some embodiments, the film can be an electrically conductive film. An electrically conductive film can be a metal film made from gold, silver, chromium, titanium, copper, and aluminum or some combination thereof. An electrically conductive film can also be fabricated as a transparent conductive oxide layer. A transparent conductive oxide layer can be made from indium-tin-oxide (ITO) or zinc oxide (ZnO) materials.

Embodiments having a plasmonic layer fabricated as a collection of patches or “islands” formed on a surface are now described in more detail. A plasmonic layer can be created by a plurality of patches formed or deposited on a surface. Each of the patches typically has a thickness of comparable dimension to a skin depth of a photon of light (e.g. a wavelength range of the terrestrial solar spectrum). Patches can have shapes such as rods, tubes, rectangles, triangles, linear ridges, circular ridges, spirals, spiral ridges, and stars. Each of the shapes typically has a physical dimension of about a wavelength of light, such as in a wavelength range of the terrestrial solar spectrum. Suitable pattern distributions include periodic pattern distributions, non-periodic pattern distributions, and random pattern distributions. On receiving a photon, a plasmonic layer formed from a distribution of patches can cause there to be a higher electric and/or magnetic field strength near some patches as compared to the field strength in voids (spaces) between the patches.

Patches are typically formed or distributed on a surface. In some embodiments an optically conductive substrate can provide a suitable surface. In other embodiments, patches can be formed or deposited directly on a surface of another layer, such as a wavelength conversion layer or a photovoltaic layer. Patches can be fabricated using an electrically conductive material. For example, patches can be fabricated from a metal such as gold, silver, chromium, titanium, copper, and aluminum. Or, in other embodiments, patches can be made from a transparent conductive oxide material. Suitable conductive oxides include indium-tin-oxide (ITO) or zinc oxide (ZnO).

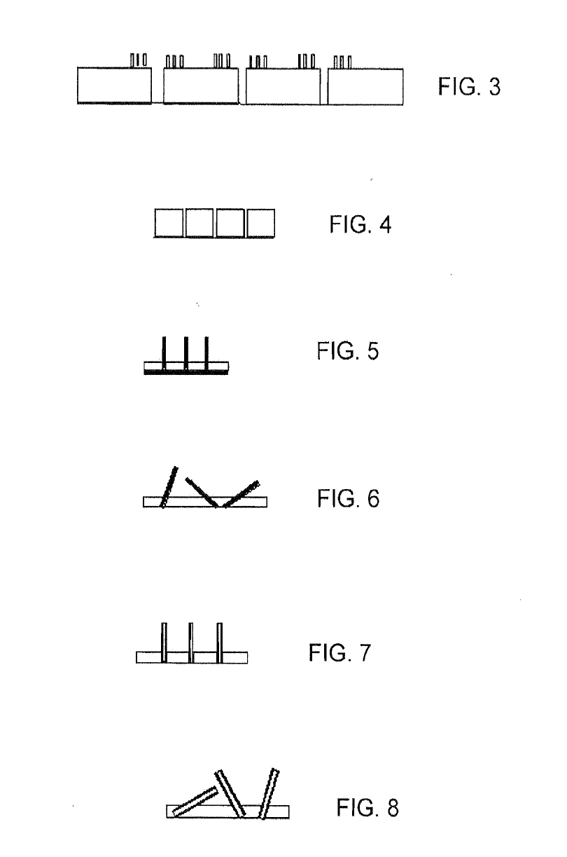

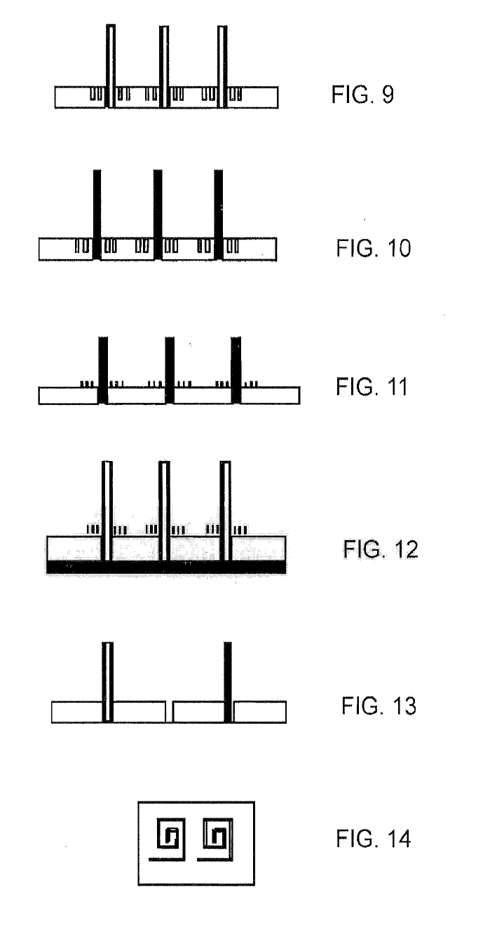

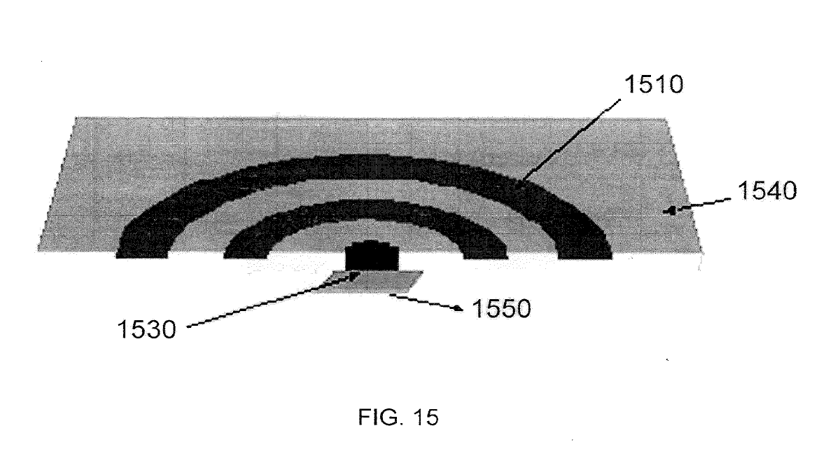

Several examples of shapes useful for plasmonic film or patch layers are now described. FIG. 3 shows a cross section drawing of a light guiding and concentrating structure having a combination of holes and surrounding ridges. FIG. 4 shows a cross section drawing of light guiding and concentrating structures having periodic holes. FIG. 5 shows a cross section drawing of light guiding and concentrating structures having a periodic array of rods. FIG. 6 shows a cross section drawing of light guiding and concentrating structures having a random array of rods. FIG. 7 shows a cross section drawing of light guiding and concentrating structures having a periodic array of tubes. FIG. 8 shows a cross section drawing of light guiding and concentrating structures having a random array of tubes. FIG. 9 shows a cross section drawing of light guiding and concentrating structures having a combination of tubes and depressions. FIG. 10 shows a cross section drawing of light guiding and concentrating structures shown as combination of rods and depressions. FIG. 11 shows a cross section drawing of a light guiding and concentrating structures having a combination of rods and ridges. FIG. 12 shows a cross section drawing of a light guiding and concentrating structures having a combination of tubes and ridges. FIG. 13 shows a cross section drawing of a light guiding and concentrating structures having a combination of hole, tube and rod. FIG. 14 shows a top view drawing of an guiding and concentrating structures having interpenetrating spiral grooves with a nanohole substantially at the center. Such structures as shown in FIG. 3 to FIG. 14 can be made with the same materials as a substrate, such as a planar substrate, or with different materials. For example, such structures can be carbon nanotubes (CNTs) grown on a non-carbon layer such as chromium, while sidewalls of the structures can be coated with a conductive material to enhance the intensity of the light or electric field. Such structures can also be embossed in a layer of film or material, such as a protective material to ensure its robustness. FIG. 15 shows one embodiment of a light concentrating, shifting and guiding structure useful for solar energy to electrical energy conversion. A sub-wavelength hole 1530 (an aperture) is surrounded by a plurality of concentric rings (periodic depressions) 1510 in a planar substrate 1540. A wavelength conversion layer 1550 is attached to the light exit side of the hole. A solar cell can include an array of such structures. Typically a planar substrate 1540 can be formed as a thin substrate, such as a film or thin film. Suitable materials for planar substrate 1540 include, but are not limited to, conductive materials that sustain surface plasmons. Examples of such materials are gold (Au), silver (Ag), copper (Cu), aluminum (Al), indium tin oxide (ITO), silicon and chromium (Cr), The planar substrate can include multiple layers of materials. Although the planar substrate material does not need to be conductive, a metallic planar substrate 1540 can sustain a surface plasmon resonance. The participation of surface resonance can alter the absorbing and concentrating effect of the structure. Although shown as a hole (sub-wavelength hole 1530) surrounded by periodic depressions (periodic depressions 1510), the structure can also take the form of other configurations including a periodic, non-periodic, or random array of apertures (e.g., holes or slits), or protrusions (e.g., rod or tubes), or depressions (e.g., dips, wells, rings, or spirals), or patches (islands), or combinations of apertures, protrusions, depressions and patches in the planar substrate, having one or more apertures (hole or slit) or tubes.

In general, light absorbing, concentrating, shifting, reemitting and guiding structures for solar energy to electrical energy conversion as described above can also include a photon conversion material (e.g. a wavelength conversion layer) to convert the incident electromagnetic waves to desired frequencies. The optical conversion materials, also referred to as wavelength conversion materials herein, can shift electromagnetic waves to higher or lower frequencies, depending on choice of the photon conversion material. Examples of suitable wavelength conversion materials include, but are not limited to, organic nonlinear optical materials (NLOs), organic and inorganic nonlinear crystals, rare earth ion doped photon-conversion materials, and luminescent quantum dots and fluorophores. Examples of these materials include, polydiacetylenes (include poly-3-butoxy-carbonyl-methyl-urethane (poly(3BCMU)) and poly-3-butoxy-carbonyl-methyl-urethane (poly(4-BCMU))), β-Barium Borate (β-BaB₂O₄ or BBO), potassium dihydrogen phosphate (KDP), potassium titanyl phosphate (KTP), lithium niobate, dendritic nonlinear organic glasses, and rare earth ions doped photon-conversion materials such as Erbium (Er³⁺), Ytterbium (Yb³⁺), Neodymium (Nd³⁺) doped polymer or glasses.

Structures to enhance plasmonic effects can include 2D periodic or non-periodic structures, and 3D periodic or non-periodic structures that can be used to enhance plasmonic effects, i.e., to enhance the electric and/or magnetic fields, concentrating and guiding light. As described in more detail below, such structures can be used in solar applications, such as solar cell applications, to guide light, and/or to improve the efficiency of wavelength conversion materials to solar efficiency. For example, plasmonic structures can be used to generate enhanced electric and/or magnetic fields, and/or to control the emission environment of wavelength shifting materials to enhance radiative rates, and therefore to increase wavelength-shifting efficiency. Typically when a wavelength shifting material absorbs a photon, two processes occur: radiative decay (i.e., spontaneous emission, light emission) and non-radiative decay (i.e., heat). In up-shifting wavelength conversion materials, the wavelength conversion process is generally nonlinear. Enhancing electric and/or magnetic field can quadruply increase the intensity of radiative decay, and therefore the wavelength conversion efficiency. For all wavelength conversion materials, both up-shifting and down-shifting, linear and nonlinear, plasmonic structures can be used to form an environment that facilitates the radiative decay, therefore a speeding up radiative decay cycle, thus enhancing the radiative decay and therefore increasing the efficiency of a solar cell. In addition to enhancing the rate of radiation, plasmonic structures can also direct the emission light. Such structures can be included in solar application to guide incident, shifted, and re-emitted light to solar cell for improved solar cell efficiency. Multiple types of structures can be used, for example, a first structure for enhancing electric/magnetic field for enhanced wavelength conversion, and a second structure for enhancing radiative decay rate for enhanced wavelength conversion, and a third structure for guiding the light to a solar cell. Alternatively, a plasmonic structure can have multiple above said functions.

### Photovoltaic Layer

As described above, a photovoltaic layer is optically coupled to other layers of the integrated solar cell structure. One or more photons of the incident light can be directly converted by photovoltaic layer to electrical energy. Or, in cases where most or all of the energy of the incident light is not within a bandwidth suitable for direct conversion by photovoltaic layer, a photovoltaic layer can convert photons of a second wavelength (a converted wavelength) to electricity, or a photovoltaic layer can convert both incident light (un-converted wavelengths) and light of a second (converted) wavelength to electricity.

The photovoltaic layer can be fabricated from any suitable photovoltaic material, such as an amorphous silicon photovoltaic material, a micro-crystalline silicon photovoltaic material, a nano-crystalline silicon photovoltaic material, a crystalline silicon photovoltaic material, a cadmium telluride (CdTe) photovoltaic material, a copper indium germanium selenium (CIGS), or an organic photovoltaic material.

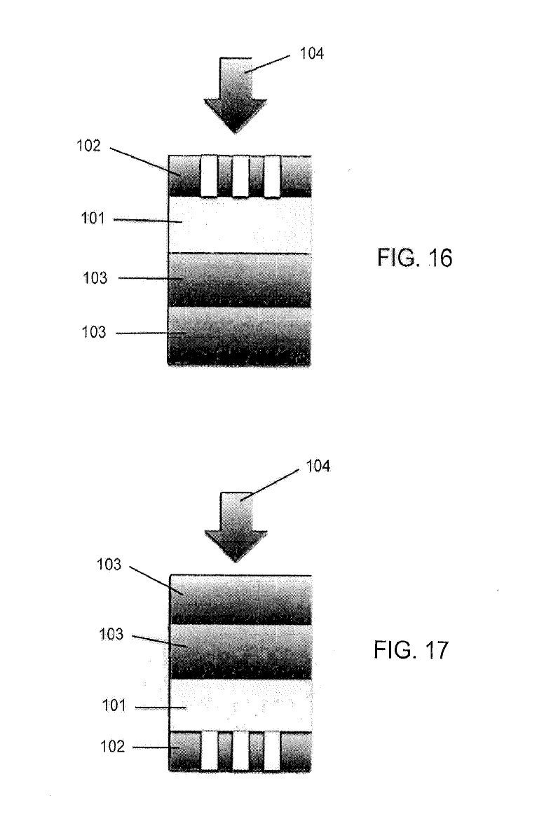

FIG. 16 shows a block diagram of an exemplary integrated solar cell with a down shifting wavelength conversion layer 101 having a plurality of photovoltaic layers 103. Typically, but not necessarily, such multiple photovoltaic layers 103 can have different, but overlapping, light to electricity wavelength conversion bandwidths. Also, as show in the example, each one of the multiple photovoltaic layers 103 can be made from a different type of a material, such as, for example, an amorphous silicon layer adjacent to a microcrystalline silicon. FIG. 17 shows a block diagram of an exemplary integrated solar cell with an up shifting wavelength conversion layer 101 having a plurality of photovoltaic layers 103.

### Optically Transparent Conductive Lam

Substantially optically transparent electrically conductive layers can be disposed between any of the layers of an integrated solar cell to improve electrical contact between the layers, For example, a substantially optically transparent electrically conductive layer can be disposed between a plasmonic layer and a wavelength conversion layer to improve electrical contact between the plasmonic layer and the wavelength conversion layer. Or, a substantially optically transparent electrically conductive layer can be disposed between a wavelength conversion layer and a photovoltaic layer to improve electrical contact between the wavelength conversion layer and the photovoltaic layer,

Example of an Integrated Solar Cell with two Plasmonic Layers

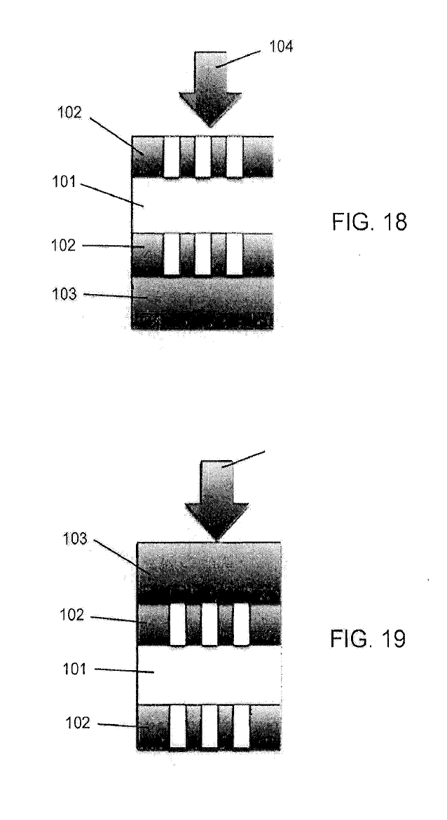

FIG. 18 shows an exemplary block diagram of an integrated solar cell with a down shifting wavelength conversion layer 101 having two plasmonic layers 102. In this embodiment, a first plasmonic layer is disposed adjacent to a first surface of the wavelength conversion layer 101 and a second plasmonic layer 102 is disposed between a second surface of the wavelength conversion layer and a photovoltaic layer 103. FIG. 19 shows an exemplary block diagram of an integrated solar cell with an up shifting wavelength conversion layer 101 having two plasmonic layers 102.

### Wavelength Conversion Layer

As described above, a wavelength conversion layer (wavelength shifting) can be optically coupled to other layers of integrated solar cell including one or more plasmonic layers and one or more photovoltaic layers, A wavelength conversion layer typically receives as input at least one photon having a first wavelength and provides as output at least one photon having a second wavelength different than the first wavelength. A down shifting wavelength conversion layer converts at least one photon having a first wavelength to at least one photon having a second wavelength longer than the first wavelength. An up shifting wavelength conversion layer converts at least one photon having a first wavelength to at least one photon having a second wavelength shorter than the first wavelength.

Down shifting wavelength conversion layers are now described in more detail. A down shifting wavelength conversion layer can include a phosphor, a fluorophore, or a quantum dot material, and can be doped with one or more rare earth ions. A down shifting wavelength conversion layer can include a material doped with a first rare-earth ion and a second rare earth ion, wherein the first rare-earth absorbs at least one photon having the first wavelength and the second rare earth ion emits at least one photon having the second wavelength longer than the first wavelength. Exemplary rare earth ions suitable for use in a down shifting wavelength conversion layer include Pr³⁺, Eu³⁺, Ce³⁺, Tm³⁺, and Yb³⁺.

The wavelength conversion layer can include a substantially optically transparent matrix. The substantially optically transparent matrix can be, for example, a glass matrix, a ceramic matrix, or a polymer matrix. Some wavelength conversion materials are of crystal form and may be formed by cooling of a molten state of the mixture of the components of wavelength conversion materials and glass or ceramic matrix. Resulting is a wavelength conversion layer with wavelength material crystallized in a transparent matrix. A wavelength conversion layer can also be formed by dispersing wavelength conversion materials in a transparent matrix such as a polymer during the formation of the matrix. Or, when a wavelength conversion layer is fabricated using a substantially transparent adhesive, the matrix solidifies to “fix” a distribution of materials. A wavelength conversion layer can also include a plurality of quantum dots. In some embodiments, a wavelength conversion layer can also be doped with a conductive element and so that the wavelength conversion layer is electrically coupled to an adjacent layer.

Up shifting wavelength conversion layers are now described in more detail. An up shifting wavelength conversion layer can include a material doped with a first rare-earth ion and a second rare earth ion. The first rare-earth ion is configured to absorb at least one photon having a first wavelength and the second rare earth ion is configured to emit at least one photon having a second wavelength shorter than the first wavelength. An up shifting wavelength conversion layer can include at least one rare earth ion such as Er³⁺, Yb³⁺, and Nd³⁺. An up shifting wavelength conversion layer can also include a substantially optically transparent matrix. The substantially optically transparent matrix can include a material such as glass, ceramic, or polymer. Or, the substantially optically transparent matrix can be made from a substantially transparent adhesive.

A nonlinear material of an up shifting wavelength conversion layer can absorb two photons having a first wavelength and output at least one photon having a second wavelength that is substantially one half of the first wavelength. Similarly, a nonlinear material can absorb three photons having a first wavelength and provide as output light at least one photon having a second wavelength that is substantially one third of the first wavelength.

Exemplary materials suitable for forming a wavelength conversion layer include organic material, inorganic material, optical material, and crystal material. A wavelength conversion layer can also include materials such as β-Barium Borate (BBO), potassium dihydrogen phosphate (KDP), potassium titanyl phosphate (KTP), and Lithium Niobate (LiNbO3). A wavelength conversion layer can also be doped with a conductive element so that the wavelength conversion layer is electrically coupled to an adjacent layer.

Also, note that with regard to both down shifting and up shifting wavelength conversion layers, an integrated solar cell can have two or more wavelength conversion layers. For example, there can be one or more down shifting wavelength conversion layers in addition to one or more up shifting wavelength conversion layers. Or, in other embodiments there can be one or more down shifting wavelength conversion layers having different wavelength bandwidths.

Also, a wavelength conversion layer can include one or more semiconducting materials. The one or more semiconducting materials can cause a broadening in a bandwidth of the absorption wavelength of the wavelength conversion layer.

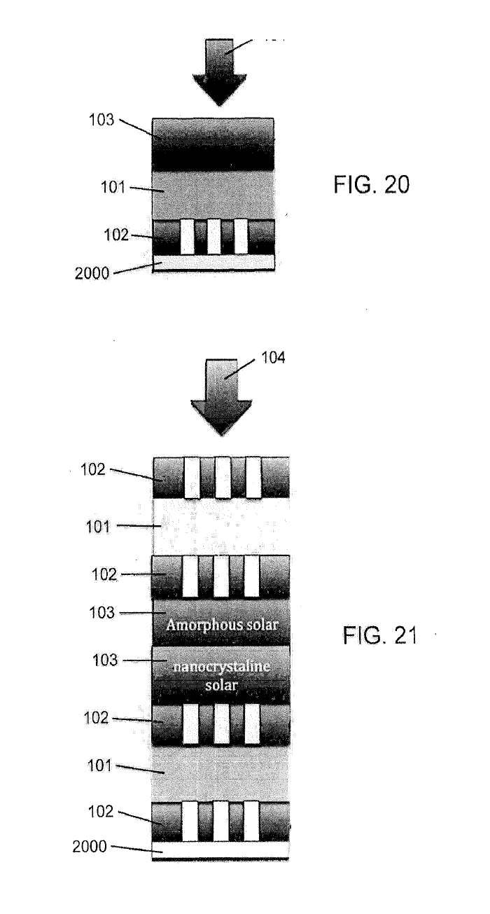

Examples, Integrated solar cell with Reflector Mirror: FIG. 20 shows a block diagram of an exemplary embodiment of an integrated solar cell with wavelength conversion having a reflector, and receiving as input, an incident light 104. Photovoltaic layer 103, wavelength conversion layer 101, and plasmonic layer 102 operate as described above. A reflector mirror layer 2000 is in optical communication with the other layers, including plasmonic layer 102, Reflector mirror layer 2000 is configured to reflect at least one photon of the incident light and at least one photon having the second (converted) wavelength towards back towards the plasmonic layer 102.

FIG. 21 shows another exemplary embodiment of an integrated solar cell with wavelength conversion and a reflector layer 2000, The embodiment of FIG. 21 is merely representative of the ways in which multiple layers can be used. Here, there can be both a down shifting wavelength conversion layer 101 (e.g. near the plasmonic layer 102 at the top of FIG. 21) and an up shifting wavelength conversion layer 101 (closer to the reflector 2000 in FIG. 21). The embodiment of FIG. 21 also illustrates the use of multiple plasmonic layers 102 (four layers of FIG. 21) and multiple photovoltaic layers 103 (two in FIG. 21). There can be any number of layers such as including, photovoltaic layers 103, wavelength conversion layers 101, and/or plasmonic layers 102.

As in earlier embodiments described above, an integrated solar cell with wavelength conversion and a reflector layer 2000 can also include one or more substantially optically transparent electrically conductive layers disposed between any two layers of the integrated solar cell. The substantially optically transparent electrically conductive layers can improve an electrical contact between any two layers of the integrated solar cell.

Part III, Integrated Films with Wavelength Shifting

An integrated film can include any of the plasmonic layers and any of the wavelength shifting layers described hereinabove in part II, Integrated films, however, generally do not include a photovoltaic layer.

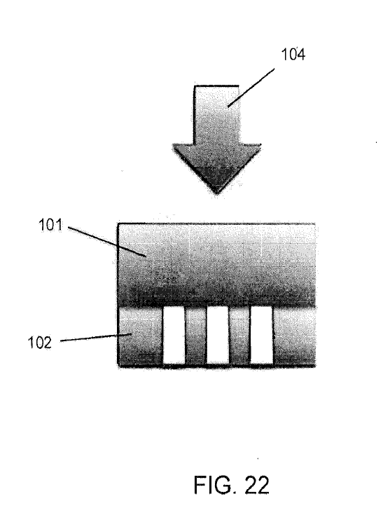

FIG. 22 shows one exemplary embodiment of an integrated film with a wavelength shifting layer, The integrated film of FIG. 22 has a plasmonic layer 102 comprising a pattern configured to support plasmon waves. The plasmonic layer 102 can be configured to receive as input light energy of an incident light 104 including at least one photon having a first wavelength and an at least one photon of light received from one or more layers in optical communication with plasmonic layer 102 and to re-emit as output a guided light to the one or more layers in optical communication with plasmonic layer 102. The integrated film also includes a wavelength conversion layer 101 that is optically coupled to plasmonic layer 102. Wavelength conversion layer 101 can be configured to receive as input the at least one photon having a first wavelength and to provide as output at least one photon having a second wavelength different than the first wavelength. The guided light can also be concentrated (e.g. focused) by a plasmonic layer 102 to create a concentrated light. An incident light 104 can include light generated by any terrestrial or extraterrestrial light sources including, but not limited to, the sun, engines, human bodies, electronics.

The plasmonic layer 102 of an integrated film can include any of the features, properties, and/or materials described above in part II. Similarly the wavelength conversion layer 101 of an integrated film can include any of the features, properties, and/or materials described above in part II, Also, an integrated film can have one or more plasmonic layers 102 and/or one or more wavelength conversion layers 101. An integrated film can also include an additional reflector layer 2000 as described above in part II.

Camouflage Films: An integrated film with wavelength shifting as described above can be used as a camouflage film to make various types of camouflage apparatus. The phrases used herein to describe various embodiments of camouflage apparatus, such as and including, camouflage film, camouflage clothing, and camouflage fabric are used interchangeably for military and civilian applications as well as interchangeably for applications for camouflage (minimizing visual detection) and/or applications for controlling the temperature of a body or inanimate object in a volume covered by or otherwise contained within or behind a camouflage apparatus based on an integrated film (including, for example, applications where only temperature control is desired).

For example, a camouflage film can be configured to shift a photon of light radiated from a human body or a building, engine to a photon of light having a wavelength outside of a detection range of a selected one of an IR detector and a human eye. As is well know, all bodies, including human, animal, and inanimate bodies, radiate heat, typically including radiated heat over a wide range of IR wavelengths. A camouflage apparatus, such including camouflage fabrics, camouflage clothing, and other types of camouflage films, can convert IR radiation received on a first side of the camouflage apparatus to a second wavelength that is emitted from the second side out into a space past the second side. The camouflage apparatus can be configured such that one or more photons emitted from the second side at the second wavelength fall in a range of wavelength substantially not visible to an electronic IR detector or to the human eye. In other embodiments, a camouflage film can emit light substantially at a wavelength that is absorbed by atmospheric water, thus creating a range at which an object behind or within such a camouflage apparatus can be masked by the atmospheric water absorption. Also, a camouflage film can include a plurality of plasmonic layers configured to guide an output light in a pre-determined direction.

Camouflage films can also be used as an element of an article of clothing. For example, an article of clothing can include one or more layers of a fiber or cloth. A wavelength shifting layer can be disposed near a plasmonic layer so that the wavelength shifting layer still remains in optical communication with the plasmonic layer. An article of clothing can include any typical article of clothing such as a jump suit, soldier's uniform or fatigues, pants, trousers, shirts, jackets, hats, gloves, socks, coats, etc. An article of clothing typically has an inner volume adapted to cover at least part of a human body and an outer surface. The article of clothing can be configured to accept a radiated heat from the inner volume of the clothing and to re-emit via the outer surface to a space outside of the clothing one or more photons having a different wavelength than the radiated heat. Thus, such an article of clothing can function as a camouflage apparatus as described above, For example, the article of clothing can be configured where one or more photons that are re-emitted via an outer surface to a space outside of the clothing are substantially at a wavelength outside of a detection range of an IR detector or a human eye.

Another use of such articles of clothing is to help control or regulate the temperature of a body wearing clothing based on an integrated film with wavelength shifting. For example in cooler or cold weather, the article of clothing can be configured to redirect a portion of heat radiated from a body within an inner volume of the clothing back into the inner volume to help minimize heat loss from a body, e.g. to keep a person wearing the clothing warm. Or, in other embodiments, in warmer or hot weather, the article of clothing can be configured to direct substantially all of the radiated heat from the inner volume of the clothing to an outer surface to maximize heat loss from the body, such as to keep a person wearing the clothing cool.

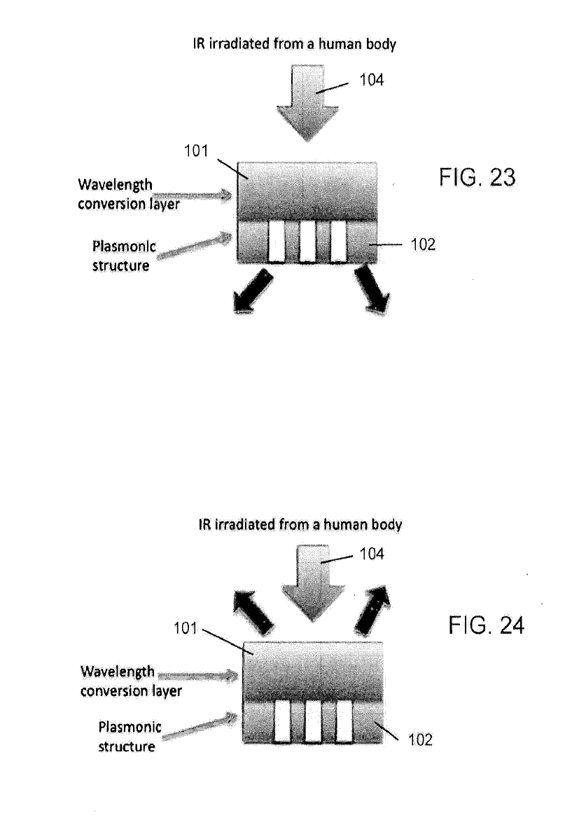

Another use of such articles of clothing is to camouflage as well as to help control or to regulate the temperature of a body wearing clothing based on an integrated film with wavelength shifting. In such an arrangement, one or more plasmonic layers are used to guide the heat radiated directly from a body and/or the shifted radiation emitted from wavelength conversion layer. For example in cooler or cold weather, the article of clothing can be configured to redirect all or a portion of heat radiated from a body within an inner volume of the clothing and the shifted radiation back into the inner volume to help minimize heat loss from a body, e.g. to keep a person wearing the clothing warm. Or, in other embodiments, in warmer or hot weather, the article of clothing can be configured to direct substantially all of the radiated heat from the inner volume of the clothing to wavelength conversion layer for shifting and then direct the shifted radiation to an outer surface to maximize heat loss from the body, such as to keep a person wearing the clothing cool. FIG. 23 shows one exemplary embodiment of an integrated film suitable for use in an article of clothing to keep a person warm. FIG. 24 shows one exemplary embodiment of an integrated film suitable for use in an article of clothing to keep a person cool

In other embodiments, a camouflage film can be configured as an element of an article of camouflage cover. An article of camouflage cover can include one or more layers of a fiber, cloth, or metal. A wavelength shifting layer can be disposed near a plasmonic layer such that the wavelength shifting layer remains in optical communication with the plasmonic layer. The article of camouflage cover can include an inner volume adapted to cover at least part of an object. Objects can include virtually any physical object that can be covered, such as, for example a machine, an engine, a tank, a tent, a building, a vehicle, an aircraft, a boat, and a ship. A camouflage cover can be configured to accept a radiated heat from an inner volume (e.g. a volume under, behind, or otherwise covered by a camouflage cover). The camouflage cover re-emit via an outer surface to a space outside of the camouflage cover one or more photons having a different wavelength than a heat radiated from within or behind the camouflage cover. The camouflage cover can be configured such that one or more photons are re-emitted via the outer surface to a space outside of the camouflage cover at substantially a wavelength outside of a detection range of an IR detector or a human eye.

In temperature control applications, a camouflage cover can also be configured to redirect a portion of radiated heat from the inner volume of the camouflage cover back into an inner volume to minimize a rate of heat loss of the object. Or, in other embodiments, a camouflage cover can also be configured to direct substantially all of the radiated heat from an inner volume of the camouflage cover to an outer surface to maximize a heat loss from the object. Also in temperature control applications, a camouflage cover can be more made configurable where at least one plasmonic layer is configured to be removed from an article of camouflage cover. For example, a plasmonic layer can be configured to be removed by a mechanical means, such as an electric motor. In still more sophisticated temperature control applications, the movement of a mechanically configurable plasmonic layer can be controlled by a thermostat.

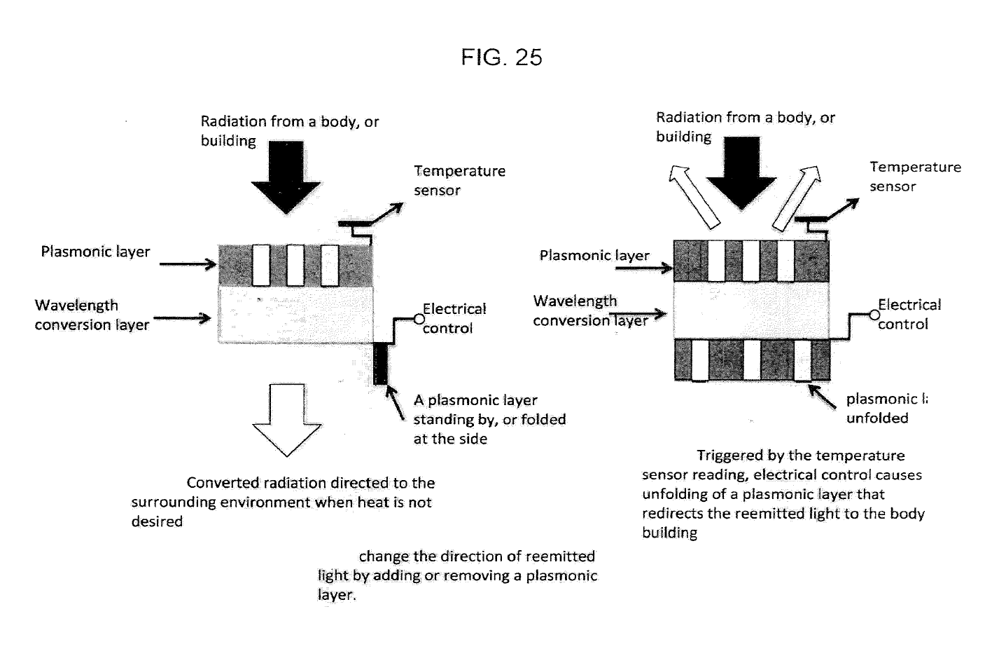

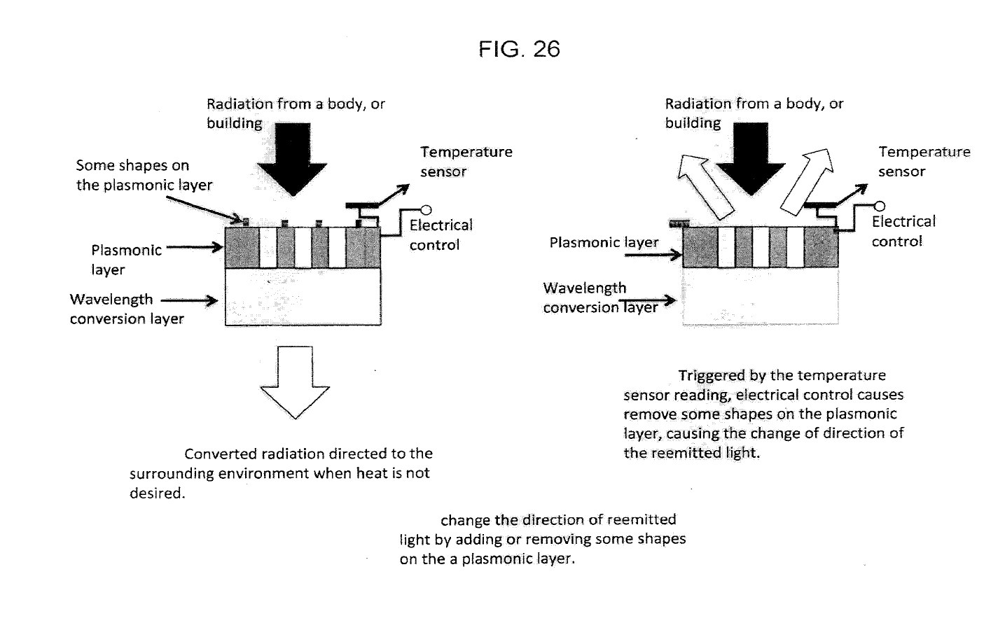

In camouflage and temperature control applications, a camouflage cover can also be configured to redirect a portion of radiated heat from the inner volume of the camouflage cover as well as shifted radiation back into an inner volume to minimize a rate of heat loss of the object. Or, in other embodiments, a camouflage cover can also be configured to direct substantially all of the radiated heat from an inner volume of the camouflage cover to a wavelength conversion layer and then to direct the shifted radiation to an outer surface to maximize a heat loss from the object. Also in temperature control applications, a camouflage cover can be more made configurable where at least one plasmonic layer is configured to be removed from an article of camouflage cover. For example, a plasmonic layer can be configured to be removed by a mechanical means, such as an electric motor. In still more sophisticated temperature control applications, the movement of a mechanically configurable plasmonic layer can be controlled by a thermostat. FIG. 25 shows a block diagram of a mechanically moveable or retractable plasmonic layer. On the left side of FIG. 25, the layer has been retracted, e.g. folded to one side as, for example, in a mechanical accordion folded style. In this exemplary embodiment, when the plasmonic layer is standing by in a folded position, radiation from a body or building is shifted to a radiation not detectable by an IR detector of human eye and radiated to a surrounding environment, such as when heat is not desired. On the right side of FIG. 25, the accordion layer is unfolded, opened or restored. In the unfolded position, radiation from a body or building can be redirected back to the body or building, such as, for example, to provide heating, or to reduce heat loss. The operation of the folded plasmonic layer of FIG. 25 can be controlled by a combination of a temperature sensor and an electrical control.

FIG. 26 shows another embodiment of a temperature controlling integrated film. In FIG. 26, plasmonic shapes are distributed in a plasmonic pattern on the left side of the page. In this exemplary embodiment, radiation from a body or building is converted to radiation of another wavelength and radiated to an outside environment, such as when heat is not desired at the body or building. On the right side, a substrate has been retracted, such as to pull all of the shapes close together and away from a plasmonic layer surface operating area, thus precluding light guiding by the plasmonic layer. Here, radiation from a body or building is reflected back to the body or building when the plasmonic shapes are retracted. The operation of mechanically configurable plasmonic layers can be controlled by a thermostatic control (temperature sensor and electrical control in FIG. 26), such as by an electronic thermostat controlling an electric motor that extends or retracts a plasmonic layer.

Another embodiment of a camouflage cover can include multiple plasmonic layers where one or more layers can be removed or re-added to change the direction of the radiation, such as both an incident or re-emitted radiation. The addition or removal of one or more layers can be achieved by any suitable mechanical or electrical means, such as was described above. For example, in some embodiments, a mechanical spring can be embedded in a removable plasmonic layer as a backbone. Forces can be applied, for example, on both sides of the spring to keep the plasmonic layer present in the path of radiation. Then, as desired, forces that keep the spring open can be removed to retract or fold the layer to remove it from the path of the light. In still other embodiments, a foldable rod attached to a removable plasmonic layer as a backbone can be connected to an electrical motor. When desired, the motor can operate to roll or fold the plasmonic layer and remove it from the path of radiation. Also, in any of the above embodiments, one or more temperature sensors can be built into the integrated film.

Regarding the above camouflage and thermal applications, typically, heat generated by a warm body (human or engines) covers a large range of wavelengths from ˜2 micron to ˜20 micron. Most IR detectors can only see radiation at a mid-range IR (3-5 um) or a long-wavelength IR (8-12 um). Water absorbance is generally at about 6-7 um. Therefore, for a camouflage device, the integrated film can shift all or most heat from a warm body to the ranges that fall into gaps of the various commonly used IR detectors and/or into to the water absorbance band. Note that in some embodiments, the shifted wavelength is still within IR range (heat).

Night Vision Apparatus: An integrated film can be configured as a receiving element for a night vision apparatus. The receiving element can be configured to shift an incident light to a wavelength that is detectable by an IR detector or a human eye. Such receiving element can include one or more optical lenses. The one or more optical lenses can be configured to correct for the near-sighted or far-sighted vision of a human observer. The one or more optical lenses can also be configured to improve the intensity of an incident light and/or to clarity an object viewable via an incident light. A plasmonic layer can be configured to guide a light of a second wavelength to either a human eye or to an optical surface, such as a face of goggle.

Greenhouse Applications: An integrated film can also be configured as a greenhouse cover to convert an incident light (typically a solar incident light) to a wavelength conducive to the growth of one or more types of plants. A greenhouse cover can also include a plurality of plasmonic layers configured to guide an output light in a pre-determined direction. A greenhouse cover can provide a second wavelength that is configured to be substantially at an optimal wavelength for photosynthesis. Or, in other embodiments, the second wavelength can e configured to be substantially at an optimal wavelength for heating the greenhouse. Such covers can also include multiple wavelength layers to provide light at both wavelengths conducive to plant growth and to greenhouse heating. A greenhouse cover can also include one or more additional layers of a transparent substrate. A transparent substrate can be made from a plastic.

Low E (low-emissive films): An integrated film can be configured as a low-emissive film to suppress radiative heat emission. A low-emissive film can be configured to both to transmit a visible component of incident light and to convert an infrared wavelength of the incident light to a substantially visible wavelength. A low-emissive film can include one or more layers of a transparent substrate. The one or more layers of a transparent substrate can be made from glass.

We claim:

1. An integrated solar cell comprising:
a plasmonic layer comprising a pattern configured to support plasmon waves, said plasmonic layer configured to receive as input light energy of an incident light and at least one photon of light received from one or more layers in optical communication with said plasmonic layer and to re-emit as output a guided light to said one or more layers in optical communication with said plasmonic layer;
a wavelength conversion layer optically coupled to said plasmonic layer, said wavelength conversion layer configured to receive as input at least one photon having a first wavelength and to provide as output at least one photon having a second wavelength different than said first wavelength; and
a photovoltaic layer optically coupled to both said wavelength conversion layer and said plasmonic layer, said photovoltaic layer configured to convert at least one photon having said second wavelength to electrical energy.

2. The integrated solar cell of claim 1, wherein said guided light comprises a concentrated light.

3. The integrated solar cell of claim 1, wherein said incident light comprises light falling within a terrestrial solar spectrum.

4. The integrated solar cell of claim 1, wherein said plasmonic layer comprises a film having a thickness of comparable dimension to a skin depth of a photon of said incident light.

5. The integrated solar cell of claim 4, wherein said pattern comprises a plurality of shapes selected from the group consisting of rods, rectangles, triangles, linear ridges, circular ridges, spiral ridges, and stars.

6. The integrated solar cell of claim 5, wherein each of said shapes has a physical dimension of about a wavelength of said incident light.

7. The integrated solar cell of claim 5, wherein said pattern has a pattern distribution selected from the group consisting of a periodic pattern distribution, a non-periodic pattern distribution, and a random pattern distribution.

8. The integrated solar cell of claim 5, wherein one or more of said shapes comprises a protrusion extending outward from a surface of said film.

9. The integrated solar cell of claim 5, wherein one or more of said shapes comprises a depression extending into a surface of said film.

10. The integrated solar cell of claim 5, wherein one or more of said shapes comprises a void extending trough both a first surface and a second surface of said film.

11. The integrated solar cell of claim 5, wherein one or more of said shapes comprises a void surrounded by a plurality of protrusions.

12. The integrated solar cell of claim 5, wherein one or more of said shapes comprises a void surrounded by a plurality of depressions.

13. The integrated solar cell of claim 4, wherein said film comprises an electrically conductive film.

14. The integrated solar cell of claim 13, wherein said electrically conductive film comprises a selected one of a metal and an alloy made from metals selected from the group consisting of gold, silver, chromium, titanium, copper, and aluminum.

15. The integrated solar cell of claim 13, wherein said electrically conductive film comprises a transparent conductive oxide layer.

16. The integrated solar cell of claim 15, wherein said transparent conductive oxide comprises a selected one of an indium-tin-oxide (ITO) and a zinc oxide (ZnO).

17. The integrated solar cell of claim 1, wherein said plasmonic layer comprises a plurality of patches disposed on a surface, each one of said patches having a thickness of comparable dimension to a skin depth of a photon of said incident light.

18. The integrated solar cell of claim 17, wherein each one of said patches has a shape selected from the group consisting of rods, tubes, rectangles, triangles, linear ridges, circular ridges, spirals, spiral ridges, and stars.

19. The integrated solar cell of claim 18, wherein each of said shapes has a physical dimension of about a wavelength of said incident light.

20. The integrated solar cell of claim 19, wherein said pattern has a pattern distribution selected from the group consisting of a periodic pattern distribution, a non-periodic pattern distribution, and a random pattern distribution.

21. The integrated solar cell of claim 17, wherein said surface comprises an optically conductive substrate.

22. The integrated solar cell of claim 17, wherein said surface comprises a surface of a selected one of said wavelength conversion layer and said photovoltaic layer.

23. The integrated solar cell of claim 17, wherein each one of said patches comprises an electrically conductive material.

24. The integrated solar cell of claim 23, wherein said electrically conductive material comprises a metal selected from the group consisting of gold, silver, chromium, titanium, copper, and aluminum.

25. The integrated solar cell of claim 23, wherein said electrically conductive material comprises a transparent conductive oxide layer.

26. The integrated solar cell of claim 25, wherein said transparent conductive oxide comprises a selected one of an indium-tin-oxide (ITO) and a zinc oxide (ZnO).

27. The integrated solar cell of claim 17, wherein said plasmonic layer is configured such that a received photon causes a selected one of an electric field and a magnetic field to have a higher field strength near each of said patches as compared to a field strength in a void between said patches.

28. The integrated solar cell of claim 1, wherein said photovoltaic layer comprises a photovoltaic material selected from the group consisting of an amorphous silicon photovoltaic material, a micro-crystalline silicon photovoltaic material, a nano-crystalline silicon photovoltaic material, a crystalline silicon photovoltaic material, a cadmium telluride (CdTe) photovoltaic material, a copper indium germanium selenium (CIGS), and an organic photovoltaic material.

29. The integrated solar cell of claim 1, further comprising a substantially optically transparent electrically conductive layer disposed between said plasmonic layer and said wavelength conversion layer, said substantially optically transparent electrically conductive layer configured to improve an electrical contact between said plasmonic layer and said wavelength conversion layer.

30. The integrated solar cell of claim 1, further comprising a substantially optically transparent electrically conductive layer disposed between said wavelength conversion layer and said photovoltaic layer, said substantially optically transparent electrically conductive layer configured to improve an electrical contact between said wavelength conversion layer and said photovoltaic layer.

31. The integrated solar cell of claim 1, comprising a first plasmonic layer disposed adjacent to a first surface of said wavelength conversion layer and a second plasmonic layer disposed between a second surface of said wavelength conversion layer and said photovoltaic layer.

32. The integrated solar cell of claim 1, further comprising a substantially optically transparent electrically conductive layer disposed between any two layers of said integrated solar cell, said substantially optically transparent electrically conductive layer configured to improve an electrical contact between said any two layers of said integrated solar cell.

33. The integrated solar cell of claim 1, further comprising a plurality of photovoltaic layers.

34. The integrated solar cell of claim 1, wherein said wavelength conversion layer is configured to receive as input at least one photon having a first wavelength and to provide as output at least one photon having a second wavelength longer than said first wavelength.

35. The integrated solar cell of claim 34, wherein said wavelength conversion layer comprises a selected one of a phosphor and a fluorophore.

36. The integrated solar cell of claim 34, wherein said wavelength conversion layer comprises a material doped with one or more rare earth ions.

37. The integrated solar cell of claim 34, wherein said wavelength conversion layer comprises a material doped with a first rare-earth ion and a second rare earth ion, wherein said first rare-earth ion is configured to absorb at least one photon having said first wavelength and said second rare earth ion is configured to emit at least one photon having said second wavelength longer than said first wavelength.

38. The integrated solar cell of claim 34, wherein said wavelength conversion layer comprises at least one rare earth ion selected from the group consisting of Pr³⁺, Eu³⁺, Ce³⁺, Tm³⁺, and Yb³⁺.

39. The integrated solar cell of claim 34, wherein said wavelength conversion layer comprises a substantially optically transparent matrix.

40. The integrated solar cell of claim 39, wherein said substantially optically transparent matrix comprises a material selected from the group consisting of glass, ceramic, and polymer.

41. The integrated solar cell of claim 39, wherein said substantially optically transparent matrix comprises a substantially transparent adhesive.

42. The integrated solar cell of claim 34, wherein said wavelength conversion layer comprises a plurality of quantum dots.

43. The integrated solar cell of claim 34, wherein said wavelength conversion layer is doped with a conductive element and said wavelength conversion layer is electrically coupled to at least one adjacent layer.

44. The integrated solar cell of claim 1, wherein said wavelength conversion layer is configured to receive as input at least one photon having a first wavelength and to provide as output at least one photon having a second wavelength shorter than said first wavelength.

45. The integrated solar cell of claim 1, wherein said wavelength conversion layer comprises a phosphor.

46. The integrated solar cell of claim 1, wherein said wavelength conversion layer comprises a material doped with one or more rare earth ions.

47. The integrated solar cell of claim 1, wherein said wavelength conversion layer comprises a material doped with a first rare-earth ion and a second rare earth ion, wherein said first rare-earth ion is configured to absorb at least one photon having said first wavelength and said second rare earth ion is configured to emit at least one photon having said second wavelength shorter than said first wavelength.

48. The integrated solar cell of claim 47, wherein said wavelength conversion layer comprises at least one rare earth ion selected from the group consisting of Er³⁺, Yb³⁺, and Nd³⁺.

49. The integrated solar cell of claim 47, wherein said wavelength conversion layer comprises a substantially optically transparent matrix.

50. The integrated solar cell of claim 49, wherein said substantially optically transparent matrix comprises a material selected from the group consisting of glass, ceramic, and polymer.

51. The integrated solar cell of claim 49, wherein said substantially optically transparent matrix comprises a substantially transparent adhesive.

52. The integrated solar cell of claim 47, wherein said wavelength conversion layer comprises a nonlinear material configured to absorb two photons having a first wavelength and to provide as output at least one photon having a second wavelength that is substantially one half of said first wavelength.

53. The integrated solar cell of claim 47, wherein said wavelength conversion layer comprises a nonlinear material configured to absorb three photons having a first wavelength and to provide as output at least one photon having a second wavelength that is substantially one third of said first wavelength.

54. The integrated solar cell of claim 47, wherein said wavelength conversion layer comprises at least one material selected from the group of materials consisting of organic material, inorganic material, optical material, and crystal material.

55. The integrated solar cell of claim 47, wherein said wavelength conversion layer comprises at least one material selected from the group of materials consisting of β-Barium Borate (BBO), potassium dihydrogen phosphate (KDP), potassium titanyl phosphate (KTP), Lithium Niobate (LiNbO3), polydiacetylenes, poly-3-butoxy-carbonyl-methyl-urethane (poly(3BCMU)), poly-3-butoxy-carbonyl-methyl-urethane (poly(4-BCMU))), and dendritic nonlinear organic glass.

56. The integrated solar cell of claim 47, wherein said wavelength conversion layer is doped with a conductive element and said wavelength conversion layer is electrically coupled to at least one adjacent layer.

57. The integrated solar cell of claim 1, wherein said wavelength conversion layer further comprises one or more semiconducting materials and said wavelength conversion layer is configured to broaden a bandwidth of absorption wavelength.

58. The integrated solar cell of claim 1, wherein said integrated solar cell comprises at least one additional wavelength conversion layer and at least one wavelength conversion layer configured to receive as input at least one photon having a first wavelength and to provide as output at least one photon having a second wavelength longer than said first wavelength and at least one wavelength conversion layer configured to receive as input at least one photon having a first wavelength and to provide as output at least one photon having a second wavelength shorter than said first wavelength.

59. An integrated solar cell comprising:
a photovoltaic layer configured to receive as input light energy of an incident light and to convert at least one photon having a second wavelength to electrical energy and to re-emit as output an emitted light to one or more layers in optical communication with said photovoltaic layer;
a wavelength conversion layer optically coupled to said photovoltaic layer, said wavelength conversion layer configured to receive as input at least one photon having a first wavelength and to provide as output at least one photon having said second wavelength different than said first wavelength;
a plasmonic layer comprising a pattern configured to support plasmon waves, said plasmonic layer configured to receive as input light energy of said emitted light and to re-emit as output a guided light to one or more layers in optical communication with said plasmonic layer; and
a reflector mirror layer in optical communication with said plasmonic layer and configured to reflect at least one photon of said incident light and at least one photon having said second wavelength towards said plasmonic layer.

60. The integrated solar cell of claim 59, wherein said guided light comprises a concentrated light.

61. The integrated solar cell of claim 59, further comprising a substantially optically transparent electrically conductive layer disposed between any two layers of said integrated solar cell, said substantially optically transparent electrically conductive layer configured to improve an electrical contact between said any two layers of said integrated solar cell.

62. The integrated solar cell of claim 59, further comprising at least one additional photovoltaic layer disposed between said photovoltaic layer and said reflector mirror.

63. The integrated solar cell of claim 59, further comprising at least one additional plasmonic layer disposed between any two layers of said integrated solar cell.

64. The integrated solar cell of claim 59, further comprising at least one additional wavelength conversion layer disposed between said photovoltaic layer and said reflector mirror.

65. The integrated solar cell of claim 64, wherein said integrated solar cell comprises at least one wavelength conversion layer configured to receive as input at least one photon having a first wavelength and to provide as output at least one photon having a second wavelength longer than said first wavelength and at least one wavelength conversion layer configured to receive as input at least one photon having a first wavelength and to provide as output at least one photon having a second wavelength shorted than said first wavelength.
